(19) United States
(12) Patent Application Publication
(10) Pub. No.: US 2009/0164711 A1
(43) Pub. Date: Jun. 25, 2009

(54) SEMICONDUCTOR MEMORY CONTROLLER, SEMICONDUCTOR MEMORY, AND METHOD OF CONTROLLING SEMICONDUCTOR MEMORY CONTROLLER

(75) Inventor: Yasuyuki Niwa, Chiba (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/340,964

(22) Filed: Dec. 22, 2008

(30) Foreign Application Priority Data
Dec. 25, 2007 (JP) 2007-333097

(51) Int. Cl. G06F 12/02; H03M 13/09

(52) U.S. Cl. 711/103; 714/758; 711/E12.008; 714/E11.04

(57) ABSTRACT

A semiconductor memory controller, which outputs data to be stored in a memory unit to the memory unit via a bus of N-bit width (N is an even number), executes a duplexing process on the data to generate duplicated data, simultaneously outputs the respective duplicated data to two different sections of the memory unit using N/2 bit width for each duplicated data, and stores the duplicated data in the two sections of the memory unit, respectively.

### CROSS REFERENCE TO RELATED APPLICATION

This application claims the benefit of Japanese Application No. 2007-333097 filed in Japan on Dec. 25, 2007, the contents of which are incorporated herein by this reference.

### BACKGROUND OF THE INVENTION

1. Field of the Invention

The present invention relates to a semiconductor memory controller, a semiconductor memory, and a method of controlling a semiconductor memory controller, particularly to a semiconductor memory controller that conducts a duplexing process on input data and stores the processed data in a memory unit, a semiconductor memory that includes such semiconductor memory controller, and a method of controlling such semiconductor memory controller.

2. Description of the Related Art

In recent years, development of a semiconductor memory, particularly a flash memory being a nonvolatile storage medium, has made flash memories popular and widely used as storage media in information devices such as digital cameras, etc. As such devices have come to handle data in large capacity, development of flash memories has progressed to achieve flash memories with larger capacity and which are further densified. In this respect, in recent years, NAND type flash memories in particular have come to be used frequently.

In a NAND type flash memory, electric charges injected to a charge accumulation layer from channel through an insulating film are taken as information in a form of digital bit, and information is read out by measuring a conductance change in a field effect transistor in accordance with the amount of electric charges injected to the charge accumulation layer. Differently from a DRAM, a NAND type flash memory is capable of reading out data for multiple times without having the data destroyed. In particular, the NAND type flash memory's recent achievement of large capacity owes a lot to a multivalued recording system, that is, a system that enables recording of information of two bits or more in one cell depending on the amount of electric charges.

With the NAND type flash memory, however, voltage will be applied to a selection gate of a non-selected cell by a data read-out operation. Therefore, when data read-out operations are carried out repeatedly, there are possibilities that read disturbance, which is a phenomena of stored data getting destroyed, might occur. When read disturbance occurs, there are possibilities that a read-out error (to be referred to as “error” hereinafter), in which stored data is read out as different data from the time it was written, might occur.

Therefore, in the NAND type flash memory, in a case when such error occurs, the error is detected and error correction using an error correction code is carried out. More specifically, using an error correction circuit, which functions to assign error correction codes to data and decode data, each data string will have an error correction code assigned thereto in advance before being stored in a memory unit, whereby an error in a data string to be read out from the memory unit can be corrected, in the event that such error occurs.

However, since the number of errors that can be corrected by the error correction circuit is limited to a predetermined acceptable range depending on the specification of the error correction circuit, it is expected that the NAND type flash memory will have higher read/write reliability. Especially with a NAND type flash memory of a multivalued recoding system, read/write reliability is significant.

Among the kinds of semiconductor memories, portable NAND type flash memories capable of being easily connected with or disconnected from a predetermined port such as a USB port, etc., for example, of a host such as a personal computer, etc. are being widely used as memories for cellular phones, music players, etc., mainly for the reasons that such NAND type flash memories now have larger capacity as compared to conventional portable magnetic recording media, they do not need mechanical moving parts and are therefore compact, and so forth. However, along with the NAND type flash memory's achievement of larger capacity, the influence that data errors can possibly have on the memory has become greater. Therefore, a semiconductor memory with high read/write reliability that is capable of outputting stored data more reliably has been desired, in particular.

Japanese Patent Application Laid-Open Publication No. 07-84894 discloses a writing method by which data, when it is written to a nonvolatile memory, will be written to a working memory region and a back-up memory region so that correct data will not be lost even when power function goes down during the writing operation. The memory disclosed in Japanese Patent Application Laid-Open Publication No. 07-84894 is a kind of memory for storing the so-called system control data. However, with this memory, there is a time lag between the data written to the working memory region and the data written to the back-up memory region. Therefore, there are possibilities that difference will occur between the data written to the working memory region and the data written to the back-up memory region due to change of noise, temperature, etc. generated with the passage of time.

### SUMMARY OF THE INVENTION

According to one aspect of the present invention, a semiconductor memory controller, which conducts transmission control of data directed to a memory unit of a semiconductor memory; executes a duplexing process on the data to generate duplicated data at the time when the data is outputted to the memory unit via a bus of N-bit width (N is an even number), simultaneously outputs the respective duplicated data to two different sections of the memory unit using N/2 bit width for each duplicated data, and stores the duplicated data in the two sections of the memory unit, respectively.

According to another aspect of the present invention, a semiconductor memory includes: a memory unit; a bus of N-bit width (N is an even number) which outputs data to be stored in the memory unit to the memory unit; and a semiconductor memory controller which executes a duplexing process on the data to generate duplicated data at the time when the data is outputted to the memory unit via the bus, simultaneously outputs the respective duplicated data to two different sections of the memory unit using N/2 bit width for each duplicated data, and stores the duplicated data in the two sections of the memory unit, respectively.

According to still another aspect of the present invention, a method of controlling a memory controller includes: executing a duplexing process by which data to be stored in a memory unit of a semiconductor memory is duplicated at the time when the data is outputted to the memory unit via a bus of N-bit width (N is an even number); and simultaneously outputting the respective duplicated data to two different sections of the memory unit using N/2 bit width for each duplicated data, and storing the duplicated data in the two sections of the memory unit, respectively.

### BRIEF DESCRIPTION OF THE DRAWINGS

FIG. 1 is a configuration diagram for explaining an operation of a semiconductor memory having a semiconductor memory controller, according to a first embodiment, at the time of data writing;

FIG. 2 is a diagram for explaining data to be processed by the semiconductor memory controller according to the first embodiment of the present invention, at the time of data writing;

FIG. 3 is a configuration diagram for explaining an operation of a conventional semiconductor memory having a semiconductor memory controller, at the time of data writing;

FIG. 4 is a diagram for explaining data to be processed by the conventional semiconductor memory controller at the time of data writing;

FIG. 5 is a flow chart for explaining a flow of a data read-out process by the semiconductor memory controller according to the first embodiment;

FIG. 6 is a configuration diagram for explaining an operation of the semiconductor memory according to the first embodiment, at the time of data read-out;

FIG. 7 is a flow chart for explaining a flow of a data read-out process by a semiconductor memory controller according to a second embodiment; and

FIG. 8 is a configuration diagram for explaining an operation of a semiconductor memory according to the second embodiment, at the time of data read-out.

### DETAILED DESCRIPTION OF THE INVENTION

### First Embodiment

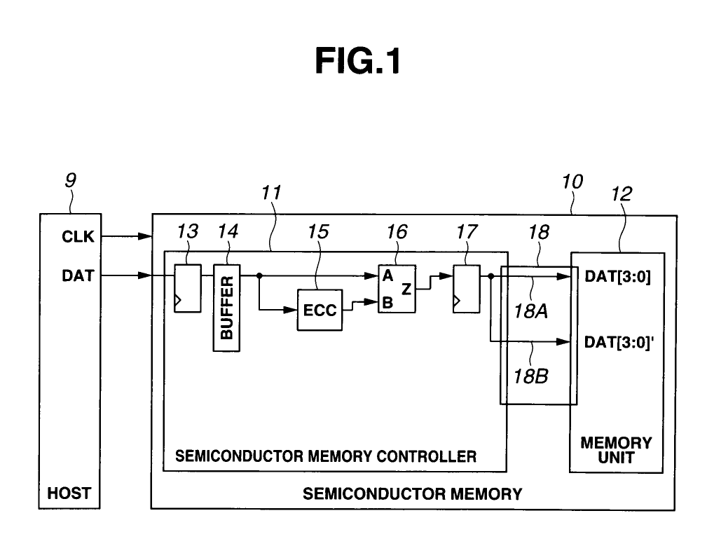

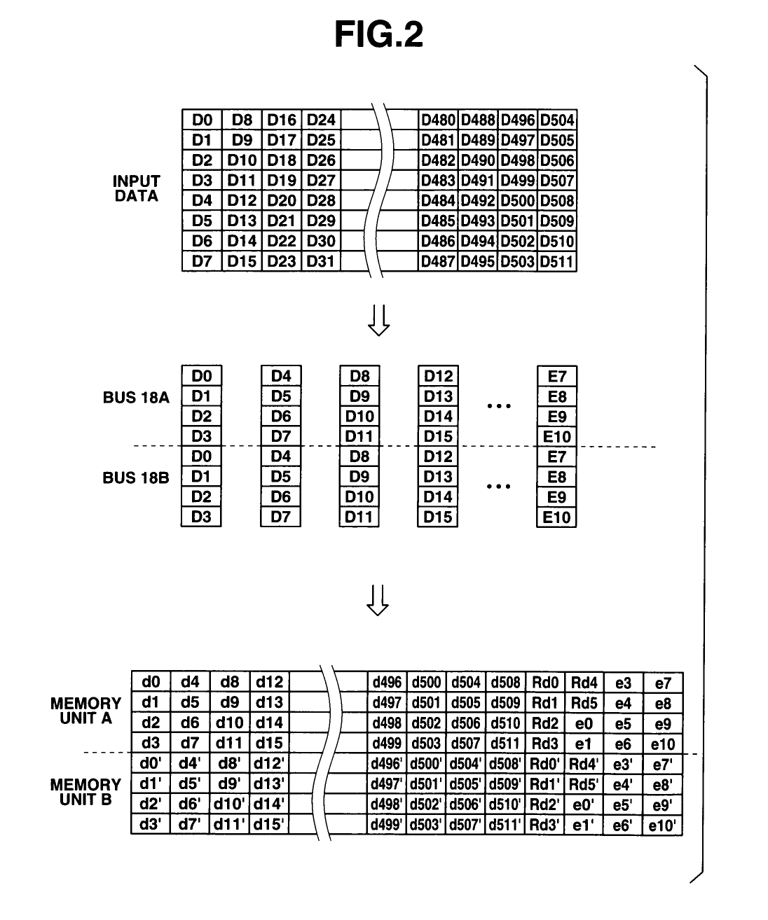

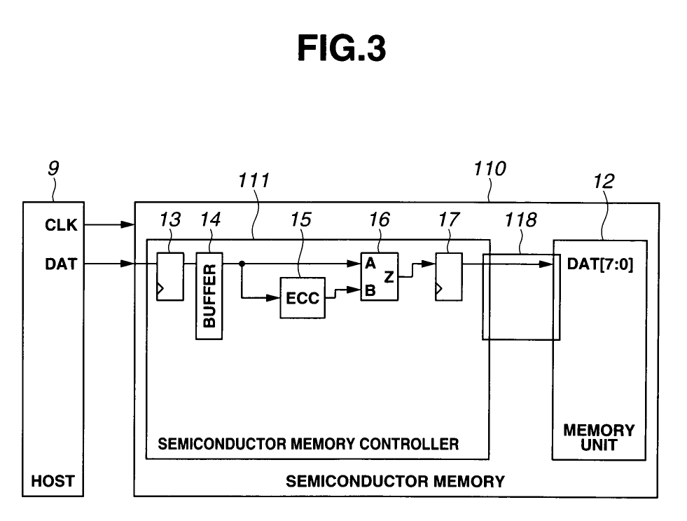

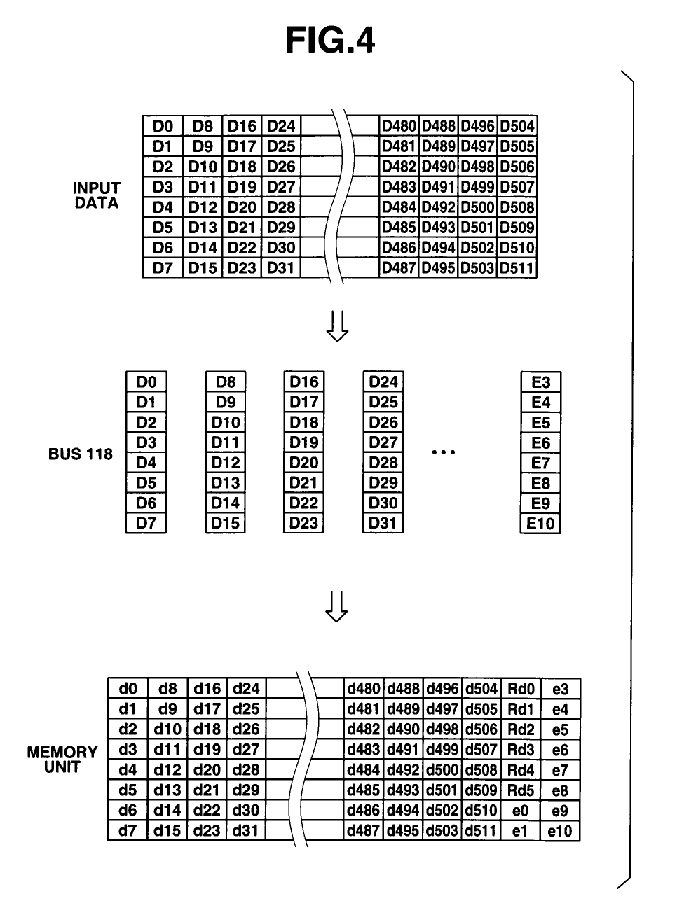

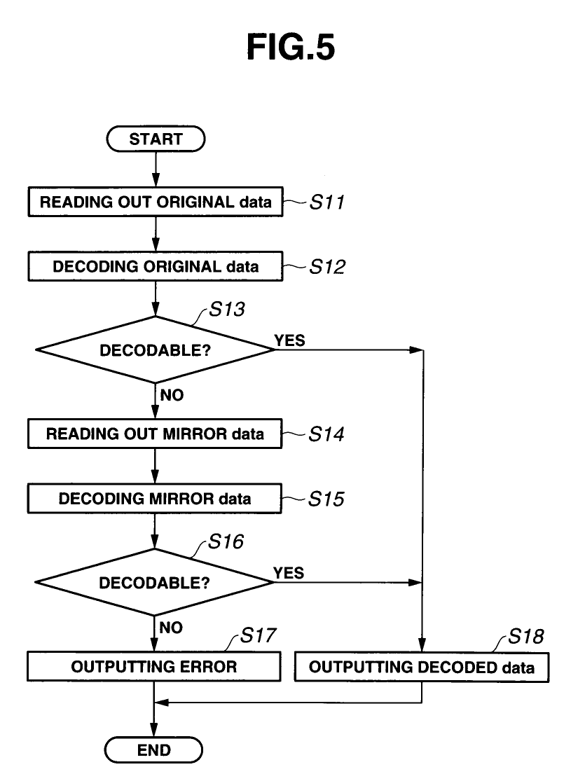

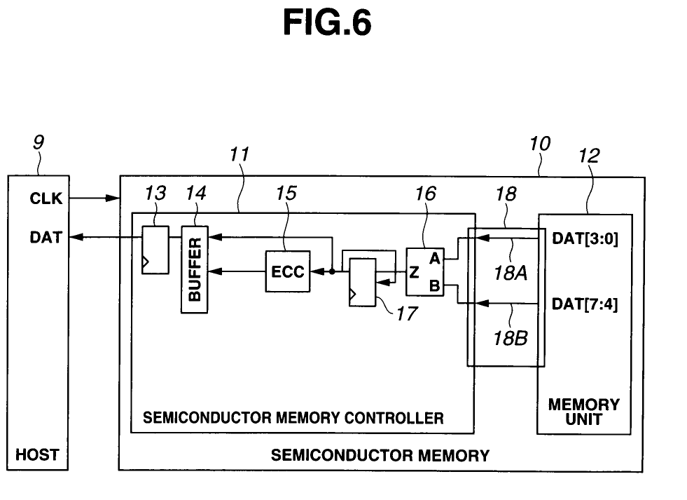

In the following, a semiconductor memory controller 11 and a semiconductor memory 10 according to a first embodiment of the present invention will be described with reference to FIG. 1 to FIG. 6. FIG. 1 is a configuration diagram for explaining an operation of the semiconductor memory 10 having the semiconductor memory controller 11, according to the present embodiment of the present invention, at the time of data writing. FIG. 2 is a diagram for explaining data to be processed by the semiconductor memory controller 11 at the time of data writing. FIG. 3 is a configuration diagram for explaining an operation of a conventional semiconductor memory 110 having a semiconductor memory controller 111, at the time of data writing. FIG. 4 is a diagram for explaining data to be processed by the conventional semiconductor memory controller 111 at the time of data writing. FIG. 5 is a flow chart for explaining a flow of a data read-out process by the semiconductor memory controller 11. FIG. 6 is a configuration diagram for explaining an operation of the semiconductor memory 10 at the time of data read-out.

As shown in FIG. 1, the semiconductor memory (to be also referred to as “semiconductor memory device” hereinafter) 10 has a memory unit 12, a semiconductor memory controller 111 which includes an error correction circuit 15, and a bus 18 which transmits data between the semiconductor memory controller 11 and the memory unit 12. The semiconductor memory 10 is a so-called USB memory which is connected to a USB terminal of a host 9 which is a digital camera, personal computer, or the like. The semiconductor memory 10 has data, clock signals and so forth inputted from the host via a USB bus, etc. The input data is stored in a buffer 14 via a register 13, and then outputted to the error correction circuit (ECC: Error Correction Code) 15 and a selector 16. The error correction circuit 15 generates an error correction code and to outputs the error correction code to the selector 16. The selector 16 generates coded data by adding the error correction code to the input data, and to outputs the coded data to a register 17. The register 17 adjusts a bit width of the coded data to a transmission width of the bus 18, and to executes a duplexing process.

The semiconductor memory controller 11 according to the present embodiment has the bus 18 of N-bit width (N is an even number). The semiconductor memory controller 11 executes a mirroring process. In the mirroring process, the semiconductor memory controller 11 executes a duplexing process on the coded data using the register 17 in order to generate two coded data of the same contents; simultaneously outputs the two coded data using N/2 bit width, i.e. each half of the bit width of the bus 18, for each coded data, to two different sections of the memory unit 12; and stores the two coded data in the two sections of the memory unit 12, respectively.

In other words, as shown in FIG. 1, the semiconductor memory controller 11 uses the bus 18 of N-bit width as two buses, 18A and 18B, each of which having a N/2 bit width, in outputting the two coded data of the same contents simultaneously to two sections of the memory unit 12 where the two coded data are stored.

The error correction circuit 15 generates an error correction code of the input data, and assigns the error correction code to the input data to generate the coded data. In addition, the error correction circuit 15 conducts error correction, i.e. decoding, of the coded data being read out from the memory unit 12. The error correction codes that the error correction circuit 15 uses may be heretofore known error correction codes such as BCH (Bose Chaudhuri Hocquengham) codes, Reed Solomon codes, etc. It is also possible to use two or more different kinds of error correction codes together.

Next, data to be processed by the semiconductor memory controller 11 at the time of data writing will be described with reference to FIG. 2. As shown in an upper part of FIG. 2, this case will show an example in which the input data will be handled as a data string of 512 bits represented as D0 to D511. The error correction circuit 15 of the semiconductor memory controller 11 generates an error correction code of 11 bits represented as E0 to E10, for instance, with respect to the data string of 512 bits, and generates a coded data string by adding the error correction code to the data string together with a redundant bit of 6 bits represented as RD0 to RD5 that includes data management information (coding step). In addition, the numbers of bits of the error correction code and the redundant bit vary greatly depending on a semiconductor memory in use, and the numbers of bits exhibited above are examples.

As shown in a middle part of FIG. 2, the semiconductor memory controller 11 executes the duplexing process on the coded data string (duplexing process step), transmits respective data to the memory unit 12 via the bus 18A and the bus 18B, each of which having a 4-bit width, and stores respective data in different memory units A and B (storing step).

In the following, the two data generated by the duplexing process will be referred to as original data and mirror data, respectively. Although the original data and the mirror data are exactly the same at least immediately after the duplexing process, the original data and the mirror data may become different in a case when error occurs due to transmission of data through the bus and reading/writing to the memory unit. For example, if the original data and the mirror data are represented by 4-bit data, the original data and the mirror data may become DAT [3:0] and DAT [3:0]′, respectively. Therefore, in a lower part of FIG. 2, the data D0 to D511 stored in the memory unit A is represented as d0 to d511, whereas the data D0 to D511 stored in the memory unit B is represented as d0′ to d511′, etc.

Now, a data writing operation of a conventional semiconductor memory 110 having a semiconductor memory controller 111 will be described with reference to FIG. 3. The conventional semiconductor memory 110 has a configuration similar to that of the semiconductor memory 10 according to the present embodiment, and therefore, the same reference numerals will be used for referring to the same configuration elements, and redundant descriptions of the configuration elements will be omitted. In detail, the configuration of the semiconductor memory 110 is similar to the configuration of the semiconductor memory 10, except that the semiconductor memory 110 outputs data by M bit-unit (M is an integer) to the memory unit 12 when the bus 18 has an M-bit width, and the outputted data is stored in one section of the memory unit 12. In this case, as shown in an upper part of FIG. 4, input data D0 to D511 processed by the conventional semiconductor memory controller 111 is the same as the input data processed by the semiconductor memory controller 11 shown in FIG. 2. Moreover, generating coded data by adding an error correction code E0 to E10 and a redundant bit RD0 to RD5 to the data string is the same as the process carried out by the semiconductor memory controller 11. However, a register 17 only adjusts a length of the coded data sting to a transmission width of a bus 118. Therefore, in this case, the data string stored in the memory unit 12 via the bus 118 shown in a middle part of FIG. 4, will be DAT [7:0] of 8-bit unit. In addition, as shown in a lower part of FIG. 4, the data string stored in the memory unit 12 is stored in only one section of the memory unit 12. That is, in the conventional semiconductor memory controller 111, data is transmitted to the memory unit 12 by 8-bit unit through the bus 118 of 8-bit width, and stored in only one section of the memory unit 12 as d0 to e10.

Next, referring to a flow chart of FIG. 5 and a configuration diagram of FIG. 6, a flow of a data read-out process by the semiconductor memory controller 11 according to the present embodiment will be described.

### <Step S11>

When the semiconductor memory 10 is connected to the host 9, power will be supplied to the semiconductor memory 10. Requested by the host 9, the semiconductor memory controller 11 reads out the original data first, from between the original data and the mirror data having been stored in the memory unit 12, via the bus 18. Although FIG. 6 shows a case in which respective 4-bit data DAT [3:0] and DAT [7:4] are read out using the bus 18A and the bus 18B, it is also possible to use only one of the buses 18A and 18B.

### <Step S12> Decoding Step

The semiconductor memory controller 11 decodes the original data.

### <Step S13> Outputting Step

In a case when the original data has been decoded normally, i.e. when the number of errors in the data is in a correctable range (step S13; Yes), the semiconductor memory controller 11 outputs the decoded original data to the host 9 at step S18.

In a case when the original data has not been decoded normally, i.e. when the number of errors in the data is over the correctable range (step S13; No), the semiconductor memory controller 11 executes processes of step S14 and the steps that follow.

### <Step S14>

The semiconductor memory controller 11 reads out the mirror data from between the original data and the mirror data having been stored in the memory unit 12, via the bus 18.

### <Step S15> Decoding Step

The semiconductor memory controller 11 decodes the mirror data.

### <Step S16> Outputting Step

In a case when the mirror data has been decoded normally, i.e. when the number of errors in the data is in a correctable range (step S16; Yes), the semiconductor memory controller 11 outputs the decoded mirror data to the host 9 at step S18.

In a case when the mirror data has not been decoded normally, i.e. when the number of errors in the data is over the correctable range (step S16; No), the semiconductor memory controller 11 outputs an error signal, etc. to the host 9 at step S17.

### <Step S17> Outputting Step

The semiconductor memory controller 11 outputs the error signal, etc. to the host 9.

### <Step S18> Outputting Step

The semiconductor memory controller 11 outputs the decoded data to the host 9.

As described above, the semiconductor memory controller 11 according to the present embodiment executes a duplexing process on the data, simultaneously outputs the duplicated data using N/2 bit width for each data to two different sections of the memory unit 12, and stores the duplicated data in the two sections of the memory unit 12, respectively. Moreover, the semiconductor memory controller 11 has the error correction circuit 15 which functions to assign error correction codes and decode data, and thus, the semiconductor memory controller 11 outputs the data which has been decoded successfully by the error correction circuit 15 from between the data being stored in the two sections of the memory unit 12.

Therefore, because the semiconductor memory controller 11 will not doubly write the same data at different timing, even if instantaneous power failure or connection/disconnection with the host occurs while data is being written to the memory unit, no difference will be caused between the recorded statuses of stored data. Moreover, since the semiconductor memory controller 11 divides the transmitting bus of the conventional semiconductor memory controller into two buses for use, there is no necessity to change the basic configuration of the conventional semiconductor memory. In other words, with the semiconductor memory controller 11, the circuit of the semiconductor memory will not become complicated or larger in size, and what is more, design changes in the circuit of the semiconductor memory can be made easily.

Moreover, the semiconductor memory controller 11 can achieve improved read/write reliability since it is capable of having not only improved read/write reliability of data due to the mirroring process but also improved read/write reliability due to the error correction circuit. Furthermore, the semiconductor memory having the semiconductor memory controller 11 can have high reliability in data writing and reading, i.e. high read/write reliability.

In particular, in a case when the memory unit is a NAND type flash memory unit, errors due to possible read disturbance may occur, and in that respect, the advantageous effect of the semiconductor memory controller 11 according to the present embodiment will become outstanding. Moreover, especially in a case when the memory unit is a NAND type flash memory unit of a multivalued recording system, the advantageous effect of the semiconductor memory controller 11 according to the present embodiment will become even more outstanding.

### Second Embodiment

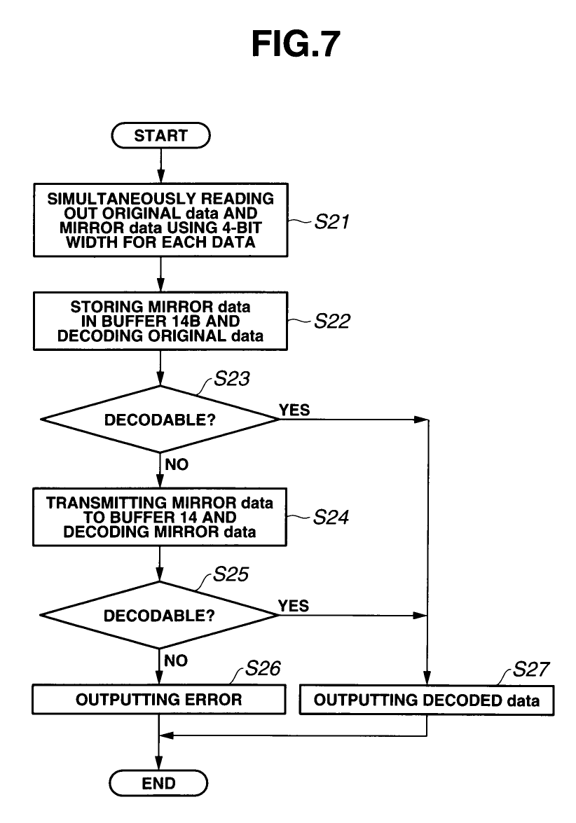

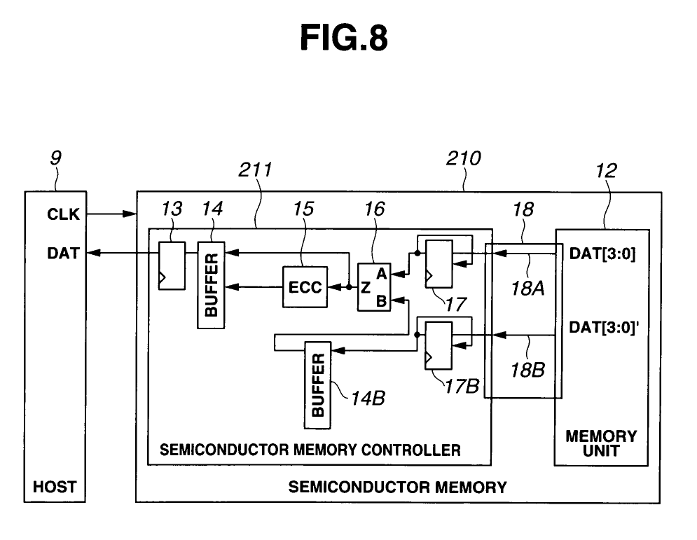

In the following, a semiconductor memory controller 211 and a semiconductor memory 210 according to a second embodiment of the present invention will be described with reference to FIG. 7 and FIG. 8. FIG. 7 is a flow chart for explaining a flow of a data read-out process by the semiconductor memory controller 211, and FIG. 8 is a configuration diagram for explaining an operation of the semiconductor memory 210 at the time of data read-out.

Since the configurations of the semiconductor memory controller 211 and the semiconductor memory 210 according to the present embodiment are similar to the ones of the semiconductor memory controller 11 and the semiconductor memory 10 according to the first embodiment, the same reference numerals will be used for referring to the same configuration elements, and redundant descriptions of the configuration elements will be omitted.

A process of coding the input data and a process of writing data to the memory unit 12 by the semiconductor memory controller 211 are the same as the ones with respect to the semiconductor memory controller 11.

Therefore, in the following, only a flow of a data read-out process by the semiconductor memory controller 211 according to the present embodiment will be described with reference to the flow chart of FIG. 7 and the configuration diagram of FIG. 8.

### <Step S21>

When the semiconductor memory 210 is connected to the host 9, power will be supplied to the semiconductor memory 210. Requested by the host 9, the semiconductor memory controller 211 simultaneously reads out the original data and the mirror data having been stored in the memory unit 12, via the bus 18A and the bus 18B, respectively, each of the buses 18A and 18B having a 4-bit width. Here, each of the buses 18A and 18B is using each half of the 8-bit width of the bus 18, i.e. each 4-bit width of the bus 18.

### <Step S22> Decoding Step

The semiconductor memory controller 211 decodes the original data having been read out from the memory unit 12 via the bus 18A. At the same time, the semiconductor memory controller 211 has the data amount of the mirror data having been read out from the memory unit 12 via the bus 18B adjusted by a register 17B before storing the mirror data to a buffer 14B.

### <Step S23> Outputting Step

In a case when the original data has been decoded normally, i.e. when the number of errors in the data is in a correctable range (step S23; Yes), the semiconductor memory controller 211 outputs the decoded original data to the host 9 at step S27.

In a case when the original data has not been decoded normally, i.e. when the number of errors in the data is over the correctable range (step S23; No), the semiconductor memory controller 211 executes processes of step S24 and the steps that follow.

### <Step S24> Decoding Step

The semiconductor memory controller 211 transmits the mirror data having been stored in the buffer 14B to the buffer 14. At the same time, the semiconductor memory controller 211 decodes the mirror data.

### <Step S25> Outputting Step

In a case when the mirror data has been decoded normally, i.e. when the number of errors in the data is in a correctable range (step S25; Yes), the semiconductor memory controller 211 outputs the decoded mirror data to the host 9 at step S27.

In a case when the mirror data has not been decoded normally, i.e. when the number of errors in the data is over the correctable range (step S25; No), the semiconductor memory controller 211 outputs an error signal, etc. to the host 9 at step S26.

### <Step S26> Outputting Step

The semiconductor memory controller 211 outputs the error signal, etc. to the host 9.

### <Step S27> Outputting Step

The semiconductor memory controller 211 outputs the decoded data to the host 9.

As described above, as in the case of the semiconductor memory controller 11 according to the first embodiment, the semiconductor memory controller 211 according to the present embodiment executes a duplexing process on the input data, simultaneously outputs the duplicated data using N/2 bit width for each data to two different sections of the memory unit 12, and stores the duplicated data in the two sections of the memory unit 12, respectively. Moreover, the semiconductor memory controller 211 has the error correction circuit 15 which functions to assign error correction codes and decode data, and thus, the semiconductor memory controller 211 will output the data which has been decoded successfully by the error correction circuit 15 from between the data being stored in the two sections of the memory unit 12.

Therefore, the semiconductor memory controller 211 and the semiconductor memory 210 are capable of achieving advantageous effects similar to those of the semiconductor memory controller 11 and the semiconductor memory 10. Moreover, the semiconductor memory controller 211 can be easily controlled, for the semiconductor memory controller 211 divides the bus of N-bit width into two to use N/2 bit widths for the data transmission in both data writing and data read-out.

In the above description, the case in which the input data string is processed by 512-bit length and read out from/written to the memory unit via the bus of 8-bit width has been referred to as an example. However, the data length, the bit width of the bus, the alignment order of the data, etc. are not limited by such example. Moreover, although the data length, etc. have been described in bit unit, they can also be described in byte unit.

Having described the preferred embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor memory controller, which conducts transmission control of data directed to a memory unit of a semiconductor memory;
the semiconductor memory controller executing a duplexing process on the data to generate duplicated data at the time when the data is outputted to the memory unit via a bus of N-bit width (N is an even number), simultaneously outputting the respective duplicated data to two different sections of the memory unit using N/2 bit width for each duplicated data, and storing the duplicated data in the two sections of the memory unit, respectively.

2. The semiconductor memory controller according to claim 1, comprising:
an error correction circuit which assigns an error correction code to the data and decodes coded data; wherein
the data to be outputted to the memory unit is rendered the coded data by having an error correction code added thereto at the time when the data is outputted to the memory unit via a bus of N-bit width (N is an even number), a duplexing process is executed on the coded data, the respective duplicated coded data are simultaneously outputted to two different sections of the memory unit by using N/2 bit width for each duplicated coded data, the duplicated coded data are stored in the two sections of the memory unit, respectively, and
the coded data which has been decoded by the error correction circuit, from between the coded data stored in the two sections of the memory unit, is outputted to the exterior at the time when the coded data stored in the memory unit is read out via the bus of N-bit width (N is an even number).

3. The semiconductor memory controller according to claim 2, wherein
the memory unit is a NAND type flash memory unit.

4. The semiconductor memory controller according to claim 2, wherein
the memory unit is a NAND type flash memory unit of a multivalued recording system.

5. A semiconductor memory comprising:
a memory unit;
a bus of N-bit width (N is an even number) which outputs data to be stored in the memory unit to the memory unit; and
a semiconductor memory controller which executes a duplexing process on the data to generate duplicated data at the time when the data is outputted to the memory unit via the bus, simultaneously outputs the respective duplicated data to two different sections of the memory unit using N/2 bit width for each duplicated data, and stores the duplicated data in the two sections of the memory unit, respectively.

6. The semiconductor memory according to claim 5, wherein
the semiconductor memory controller has an error correction circuit which assigns an error correction code to data and decodes coded data;
the semiconductor memory controller adds an error correction code to the data to generate coded data at the time when the data is outputted to the memory unit via a bus of N-bit width (N is an even number), executes a duplexing process on the coded data, simultaneously outputs the respective duplicated coded data to two different sections of the memory unit using N/2 bit width for each duplicated coded data, stores the duplicated coded data in the two sections of the memory unit, respectively, and
outputs the coded data which has been decoded by the error correction circuit, from between the coded data stored in the two sections of the memory unit, to the exterior, at the time when the coded data stored in the memory unit is read out via the bus of N-bit width (N is an even number).

7. The semiconductor memory according to claim 6, wherein
the memory unit is a NAND type flash memory unit.

8. The semiconductor memory according to claim 6, wherein
the memory unit is a NAND type flash memory unit of a multivalued recording system.

9. A method of controlling a memory controller comprising:
executing a duplexing process by which data to be stored in a memory unit of a semiconductor memory is duplicated at the time when the data is outputted to the memory unit via a bus of N-bit width (N is an even number); and
simultaneously outputting the respective duplicated data to two different sections of the memory unit using N/2 bit width for each duplicated data, and storing the duplicated data in the two sections of the memory unit, respectively.

10. The method of controlling a memory controller, according to claim 9, comprising:
executing, prior to executing the duplexing process, a coding process on the data using an error correction circuit to generate coded data;
executing the duplexing process on the coded data;
simultaneously outputting the respective duplicated coded data to two different sections of the memory unit using N/2 bit width for each duplicated coded data, and storing the duplicated coded data in the two sections of the memory unit, respectively;
decoding the coded data stored in the two sections of the memory unit, at the time when the coded data stored in the memory unit is read out via the bus of N-bit width (N is an even number); and
outputting, from between the coded data having gone through the decoding process, the data which has been decoded successfully, to the exterior.

11. The method of controlling a memory controller, according to claim 10, wherein
the memory unit is a NAND type flash memory unit.

12. The method of controlling a memory controller, according to claim 10, wherein
the memory unit is a NAND type flash memory unit of a multivalued recording system.
